(19) United States
(12) Patent Application Publication
(10) Pub. No.: US 2026/0319027 A1
(43) Pub. Date: Oct. 15, 2026

(54) MULTI-RESONANCE POINT EQUIVALENT CIRCUIT MODEL FOR INDUCTIVE MAGNETIC FIELD SENSOR AND ESTABLISHING METHOD THEREOF

(71) Applicant: AEROSPACE INFORMATION RESEARCH INSTITUTE, CHINESE ACADEMY OF SCIENCES, Beijing (CN)

(72) Inventors: Bin YAN, Beijing (CN); Wanhua ZHU, Beijing (CN); Guangyou FANG, Beijing (CN)

(73) Assignee: AEROSPACE INFORMATION RESEARCH INSTITUTE, CHINESE ACADEMY OF SCIENCES, Beijing (CN)

(21) Appl. No.: 19/646,918

(22) Filed: Apr. 14, 2026

(30) Foreign Application Priority Data
Apr. 15, 2025 (CN) 202510468253.X

(51) Int. Cl. G01R 33/028

(52) U.S. Cl. CPC G01R 33/028

(57) ABSTRACT

A multi-resonance point equivalent circuit model for an inductive magnetic field sensor is provided. The sensor includes an electromagnetic induction assembly, a feedback coil, and an amplifying circuit. The multi-resonance point equivalent circuit model includes an output terminal; an RLC equivalent circuit of the electromagnetic induction assembly, including an equivalent model of a magnetic core and an RLC equivalent circuit coupled to the magnetic core; an equivalent circuit of the amplifying circuit, with one terminal connected to the RLC equivalent circuit, and the other terminal connected to the output terminal; an equivalent circuit of a negative feedback coil, with one terminal connected to the output terminal, and the other terminal coupled to the RLC equivalent circuit of the electromagnetic induction assembly; and a parallel resonance equivalent circuit, connected between the RLC equivalent circuit and the equivalent circuit of the amplifying circuit, for suppressing a resonance peak of the sensor.

### CROSS REFERENCE TO RELATED APPLICATION(S)

This application claims the benefit of priority to Chinese Patent Application No. 202510468253.X, filed on Apr. 15, 2025. The entire contents of this application are hereby incorporated herein by reference.

### TECHNICAL FIELD

The present disclosure relates to a field of electromagnetic technology, and in particular, to a multi-resonance point equivalent circuit model for an inductive magnetic field sensor and an establishing method thereof.

### BACKGROUND

An inductive magnetic field sensor is a sensor that measures changes in a magnetic field using Faraday's law of electromagnetic induction. It is widely used in fields such as geophysics, medical science, and national defense, making it one of the most common magnetic field sensors. In geophysical electromagnetic method instruments, it is extensively used in electromagnetic exploration instruments such as the Magnetotelluric method (MT), Controlled Source Audio-frequency Magnetotelluric method (CSAMT), and Transient Electromagnetic method (TEM), with a measurement frequency range covering 0.0001 Hz to 100 kHz. It is a core component of geophysical electromagnetic equipment. Inductive magnetic field sensor technology involves a series of technical challenges such as magnetic core research and development and low-frequency weak signal detection, and is a bottleneck technology hindering the independent research and development of geophysical electromagnetic exploration equipment. To achieve an optimized design of an inductive magnetic field sensor, it is necessary to establish an equivalent circuit model of the inductive magnetic field sensor. Through simulation calculation of the model, the system function of the inductive magnetic field sensor, i.e., conversion sensitivity (frequency response) of the sensor, may be obtained.

### SUMMARY

The present disclosure provides a multi-resonance point equivalent circuit model for an inductive magnetic field sensor and an establishing method.

According to an embodiment of one aspect of the present disclosure, there is provided a multi-resonance point equivalent circuit model for an inductive magnetic field sensor, where the inductive magnetic field sensor includes an electromagnetic induction assembly, a feedback coil, and an amplifying circuit, the multi-resonance point equivalent circuit model includes an output terminal; an RLC equivalent circuit of the electromagnetic induction assembly, including an equivalent model of a magnetic core and an RLC equivalent circuit coupled and connected to the magnetic core; an equivalent circuit of the amplifying circuit, where one terminal of the equivalent circuit of the amplifying circuit is connected to the RLC equivalent circuit, and the other terminal of the equivalent circuit of the amplifying circuit is connected to the output terminal; an equivalent circuit of a negative feedback coil, where one terminal of the equivalent circuit of the negative feedback coil is connected to the output terminal, and the other terminal of the equivalent circuit of the negative feedback coil is coupled and connected to the RLC equivalent circuit of the electromagnetic induction assembly; and at least one parallel resonance equivalent circuit, connected between the RLC equivalent circuit of the electromagnetic induction assembly and the equivalent circuit of the amplifying circuit, and configured to suppress a resonance peak corresponding to a resonance point within an operating frequency band of the sensor.

According to an embodiment of the present disclosure, the electromagnetic induction assembly includes the magnetic core and an induction coil wound on the magnetic core, and the RLC equivalent circuit of the electromagnetic induction assembly includes an equivalent inductance L_{pc} and an equivalent resistance R_{sc} connected in series and an equivalent capacitance C_{sc}, where the equivalent inductance L_{pc} and the equivalent resistance R_{sc} connected in series are connected in parallel across two terminals of the equivalent capacitance C_{sc}.

According to an embodiment of the present disclosure, the at least one parallel resonance equivalent circuit is provided based on resonance point information within the operating frequency band of the magnetic field sensor, and the resonance point information includes a number of resonance peaks and a frequency of the resonance point corresponding to each resonance peak.

According to an embodiment of the present disclosure, the at least one parallel resonance equivalent circuit is selectively provided according to the number of resonance peaks.

According to an embodiment of the present disclosure, a number of parallel resonance equivalent circuits provided is determined based on the number of resonance peaks.

According to an embodiment of the present disclosure, the parallel resonance equivalent circuit includes an equivalent resonant inductance Lₘ, an equivalent resonant resistance Rₘ, an equivalent resonant capacitance Cₘ, and an equivalent inter-turn capacitance Cₛₘ connected in parallel, where the equivalent resonant resistance Rₘ is connected in series with the equivalent resistance R_{sc}, and the equivalent resonant inductance Lₘ is derived from a part of the equivalent inductance L_{pc}.

According to an embodiment of the present disclosure, a solution formula for the equivalent resonant capacitance Cₘ is:

$${C}_{m} = \frac{1}{{L}_{m} \times \sqrt{{( 2 π {f}_{m} )}^{2}}} ;$$

a solution formula for the equivalent resonant resistance Rₘ is:

$${R}_{m} = \frac{Q}{2 π {f}_{m} {C}_{m}} ;$$

where Lₘ is a value of the equivalent resonant inductance, fₘ is a frequency of the resonance point corresponding to the parallel resonance equivalent circuit, and Q represents a quality factor of the parallel resonance equivalent circuit.

According to an embodiment of the present disclosure, one terminal of the equivalent capacitance C_{sc} is grounded, and the other terminal of the equivalent capacitance C_{sc} is connected to the equivalent circuit of the amplifying circuit.

According to an embodiment of the present disclosure, the equivalent circuit of the negative feedback coil includes a feedback resistor R_{fb}, an equivalent inductance Lₛ of the negative feedback coil, and an equivalent resistance Rₛ of the negative feedback coil connected in series in sequence, where one terminal of the equivalent circuit of the negative feedback coil is connected to an output terminal of the equivalent circuit of the amplifying circuit, and the other terminal of the equivalent circuit of the negative feedback coil is grounded.

According to another aspect of the embodiments of the present disclosure, there is provided a method for establishing the multi-resonance point equivalent circuit model as described above, where the inductive magnetic field sensor includes the electromagnetic induction assembly, the feedback coil, and the amplifying circuit, and the method includes establishing the RLC equivalent circuit of the electromagnetic induction assembly; establishing the equivalent circuit of the amplifying circuit connected to the RLC equivalent circuit; establishing the equivalent circuit of a negative feedback coil, so as to establish an initial equivalent circuit model for the magnetic field sensor; determining resonance point information within the operating frequency band of the magnetic field sensor based on the initial equivalent circuit model for the magnetic field sensor; and providing at least one parallel resonance equivalent circuit according to the resonance point information to suppress a resonance peak corresponding to a resonance point within the operating frequency band of the sensor, so as to establish the multi-resonance point equivalent circuit model for the inductive magnetic field sensor.

### BRIEF DESCRIPTION OF THE DRAWINGS

Through the following description of the embodiments of the present disclosure with reference to the accompanying drawings, the above and other purposes, features, and advantages of the present disclosure will become more clear. In the accompanying drawings:

FIG. 1 is a schematic diagram of a single resonance point equivalent circuit model for a magnetic field sensor.

FIG. 2 is a schematic diagram of a sensitivity of a coil and a sensitivity of a magnetic field sensor.

FIG. 3 is a schematic diagram of a multi-resonance point equivalent circuit model for a magnetic field sensor according to an embodiment of the present disclosure.

FIG. 4 is a schematic diagram of an impedance test structure for a multi-resonance point equivalent circuit model for a magnetic field sensor according to an embodiment of the present disclosure.

FIG. 5a is a schematic diagram of a multi-resonance point equivalent circuit model for a magnetic field sensor according to an embodiment of the present disclosure.

FIG. 5b is a schematic flowchart of a method for establishing a multi-resonance point equivalent circuit model for a magnetic field sensor according to an embodiment of the present disclosure.

FIG. 6 is a comparison diagram of simulation results and actual test results of the sensitivity of the induced voltage according to an embodiment of the present disclosure.

FIG. 7 is a comparison diagram of simulation results and actual test results of the sensitivity of the magnetic field sensor according to an embodiment of the present disclosure.

### DETAILED DESCRIPTION OF EMBODIMENTS

Currently, the coil part (including the magnetic core) at the front end of an inductive magnetic field sensor is generally equivalent to a series resonant model of inductance, resistance, and capacitance. This model has one resonance frequency point. However, in practice, there is often more than one resonance frequency point within the sensor bandwidth, so the current equivalent circuit model of the inductive magnetic field sensor is not accurate.

The present disclosure provides a multi-resonance point equivalent circuit model for an inductive magnetic field sensor and an establishing method of a multi-resonance point equivalent circuit model for an inductive magnetic field sensor. In the multi-resonance point equivalent circuit model for the inductive magnetic field sensor, the parallel resonance equivalent circuit is provided, combined with the front-end amplifying circuit model of the sensor, to obtain the multi-resonance point equivalent circuit model of the sensor.

To make the purpose, technical solutions, and advantages of the present disclosure clearer, the present disclosure is further described in detail below in conjunction with specific embodiments and with reference to the accompanying drawings.

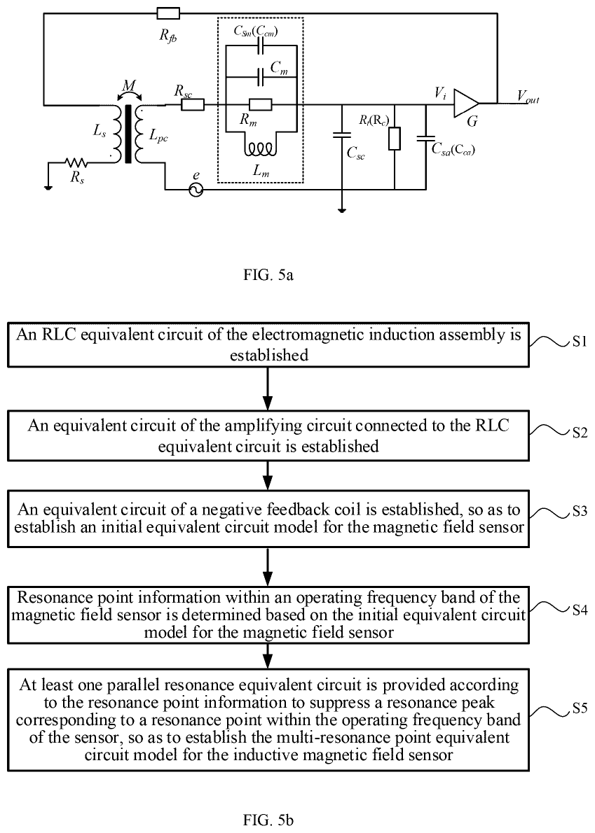

In an embodiment of the present disclosure, as shown in conjunction with FIG. 5a and FIG. 5b, a multi-resonance point equivalent circuit model for an inductive magnetic field sensor is provided. The inductive magnetic field sensor includes an electromagnetic induction assembly, a feedback coil, and an amplifying circuit. The multi-resonance point equivalent circuit model includes an output terminal; an RLC equivalent circuit of the electromagnetic induction assembly, including an equivalent model of a magnetic core and an RLC equivalent circuit coupled and connected to the magnetic core; an equivalent circuit of the amplifying circuit, where one terminal of the equivalent circuit of the amplifying circuit is connected to the RLC equivalent circuit, and the other terminal of the equivalent circuit of the amplifying circuit is connected to the output terminal; an equivalent circuit of a negative feedback coil, where one terminal of the equivalent circuit of the negative feedback coil is connected to the output terminal, and the other terminal of the equivalent circuit of the negative feedback coil is coupled and connected to the RLC equivalent circuit of the electromagnetic induction assembly; and at least one parallel resonance equivalent circuit, connected between the RLC equivalent circuit of the electromagnetic induction assembly and the equivalent circuit of the amplifying circuit, and used to suppress a resonance peak corresponding to a resonance point within an operating frequency band of the sensor.

According to an embodiment of the present disclosure, the electromagnetic induction assembly includes a magnetic core and an induction coil wound on the magnetic core, and the RLC equivalent circuit of the electromagnetic induction assembly includes an equivalent inductance L_{pc} and an equivalent resistance R_{sc} connected in series and an equivalent capacitance C_{sc}, where the equivalent inductance L_{pc} and the equivalent resistance R_{sc} connected in series are connected in parallel across two terminals of the equivalent capacitance C_{sc}.

According to an embodiment of the present disclosure, the parallel resonance equivalent circuit is provided based on resonance point information within the operating frequency band of the magnetic field sensor, and the resonance point information includes the number of resonance peaks and a frequency of the resonance point corresponding to each resonance peak. The number of parallel resonance equivalent circuits provided is determined based on the number of resonance peaks. For example, according to the number of resonance peaks, at least one parallel resonance equivalent circuit is selectively provided. If the number of resonance peaks is multiple, corresponding to multiple resonance points, one parallel resonance equivalent circuit may be provided based on a second resonance point, or another parallel resonance equivalent circuit may be provided based on a third resonance point, or more parallel resonance equivalent circuits may be provided based on actual requirements according to the number of resonance points, thereby better suppressing resonance peaks within the operating frequency band of the sensor and providing an improved equivalent model describing the sensor within a wider bandwidth.

According to an embodiment of the present disclosure, as shown in FIG. 5a, the parallel resonance equivalent circuit (shown in the rectangular dashed box in FIG. 5a) includes an equivalent resonant inductance Lₘ, an equivalent resonant resistance Rₘ, an equivalent resonant capacitance Cₘ, and an equivalent inter-turn capacitance Cₛₘ connected in parallel, where the equivalent resonant resistance Rₘ is connected in series with the equivalent resistance R_{sc}. The selection basis for the value of the equivalent resonant inductance Lₘ is that it is selected from a part of the equivalent inductance L_{pc}, i.e., a small inductance is extracted from the equivalent inductance L_{pc} as the value of the equivalent resonant inductance Lₘ.

A solution formula for the equivalent resonant capacitance Cₘ is:

$${C}_{m} = \frac{1}{{L}_{m} \times \sqrt{{( 2 π {f}_{m} )}^{2}}} ;$$

a solution formula for the equivalent resonant resistance Rₘ is:

$${R}_{m} = \frac{Q}{2 π {f}_{m} {C}_{m}} ;$$

where Lₘ is a value of the equivalent resonant inductance, fₘ is the frequency of the resonance point corresponding to the parallel resonance equivalent circuit, and Q represents a quality factor of the parallel resonance equivalent circuit. One terminal of the equivalent capacitance C_{sc} is grounded, and the other terminal of the equivalent capacitance C_{sc} is connected to the equivalent circuit of the amplifying circuit.

According to an embodiment of the present disclosure, the equivalent circuit of the negative feedback coil includes a feedback resistor R_{fb}, an equivalent inductance Lₛ of the negative feedback coil, and an equivalent resistance Rₛ of the negative feedback coil connected in series in sequence, where one terminal of the equivalent circuit of the negative feedback coil is connected to an output terminal of the equivalent circuit of the amplifying circuit, and the other terminal of the equivalent circuit of the negative feedback coil is grounded.

According to an embodiment of another aspect of the present disclosure, as shown in conjunction with FIG. 5a and FIG. 5b, there is provided a method for establishing the above multi-resonance point equivalent circuit model for an inductive magnetic field sensor, the method includes steps S1 to S5.

In step S1, an RLC equivalent circuit of the electromagnetic induction assembly is established.

In step S2, an equivalent circuit of the amplifying circuit connected to the RLC equivalent circuit is established.

In step S3, an equivalent circuit of a negative feedback coil is established, so as to establish an initial equivalent circuit model for the magnetic field sensor.

In step S4, resonance point information within an operating frequency band of the magnetic field sensor is determined based on the initial equivalent circuit model.

In step S5, at least one parallel resonance equivalent circuit is provided according to the resonance point information to suppress a resonance peak corresponding to a resonance point within the operating frequency band of the sensor, so as to establish the multi-resonance point equivalent circuit model for the inductive magnetic field sensor.

An inductive magnetic field sensor (magnetic rod) mainly includes three parts: a magnetic core, a winding coil, and a front-end amplifying circuit. The function of the magnetic core is to enhance the magnetic flux density passing through the coil, while the coil is very sensitive to changes in the ambient magnetic field. The purpose of the amplifying circuit is to amplify the tiny signal induced in the winding so that it may be detected by standard electromagnetic measurement equipment. Generally, the combination of the winding and the magnetic core may be represented as an inductive element with an inherent series resistance, connected in parallel with a capacitive element. This is a single resonance point RLC (Resistor-Inductor-Capacitor) series resonant equivalent circuit model of the magnetic field sensor. This model is the basis for understanding the sensitivity of the sensor to magnetic field changes and consists of three key components: resistance (R), inductance (L), and capacitance (C), which together determine the resonant characteristics of the sensor.

The resistance value in this equivalent circuit model corresponds to the direct current (DC) resistance of the coil, which may be easily measured using a multimeter. The inductance value may be measured using an impedance analyzer (e.g., 4294A). In practice, as the frequency increases, the impedance of the coil will transition from inductive reactance to capacitive reactance. Therefore, to accurately measure the inductance value of the coil, it is better to read the inductance value at a low frequency.

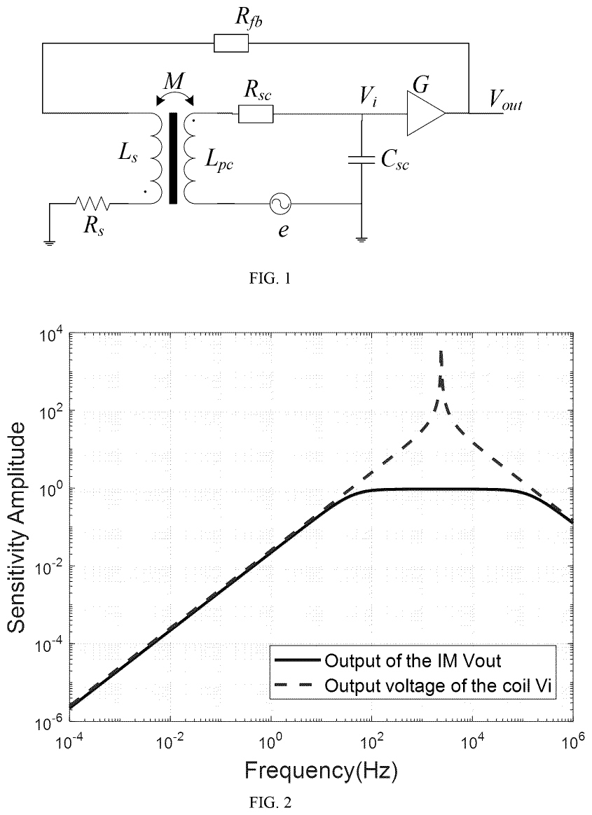

The determination of the capacitance value is a more complex process because it depends on both the measured inductance value and the resonance frequency point obtained from the impedance analyzer. The resonance frequency is the frequency at which the sensor impedance is minimum and is a key parameter in the RLC model. By combining the inductance value and the resonance frequency, the capacitance value may be calculated, thus completing the RLC model. This model is crucial for predicting the performance of the sensor and designing circuits capable of accurately detecting and measuring magnetic field changes. In summary, the equivalent circuit model of a magnetic field sensor with magnetic flux negative feedback is shown in FIG. 1, where L_{pc}, R_{sc}, and C_{sc} represent the equivalent inductance, resistance, and capacitance of the coil, respectively, e represents the induced voltage, Vᵢ represents the output voltage of the coil, Rob is the feedback resistor, G represents the equivalent gain of the amplifier, Lₛ and Rₛ represent the equivalent inductance and resistance of the negative feedback coil, M represents the mutual inductance between the induction coil and the negative feedback coil, and Vₒᵤₜ represents the output of the magnetic field sensor.

According to Faraday's law, the induced voltage e of the coil may be expressed as:

e(f)=−j2πfμₐₚₚNSB(f) (1);
where f represents frequency, μₐₚₚ represents the apparent permeability of the magnetic core, N represents the number of turns of the coil, S represents the cross-sectional area of the magnetic core, and B represents the magnetic flux density. Clearly, the induced voltage is proportional to frequency.

According to circuit principles, the output voltage Vᵢ of the coil is expressed as:

$${V}_{i} ( f ) = \frac{\frac{1}{j ω {C}_{sc}}}{\frac{1}{j ω {C}_{sc}} + {R}_{sc} + j ω {L}_{pc}} e ( f ) ; \qquad ( 2 )$$

where ω represents angular frequency, ω=2πf.

According to the solution algorithm for the transfer function in a negative feedback system, it is possible to obtain:

$$\frac{{V}_{out}}{e} = \frac{AG}{1 + AGF} ; \qquad ( 3 )$$

$$A = \frac{{V}_{i}}{e} = \frac{\frac{1}{j ω {C}_{sc}}}{\frac{1}{j ω {C}_{sc}} + {R}_{sc} + j ω {L}_{pc}} ; \qquad ( 4 )$$

$$F = \frac{e}{{V}_{out}} = \frac{\frac{{V}_{out}}{{R}_{fb} + j ω {L}_{s}} j ω M}{{V}_{out}} = \frac{j ω M}{{R}_{fb} + j ω {L}_{s}} ; \qquad ( 5 )$$

Substituting formulas (1), (4), and (5) into formula (3), the relationship between the output voltage and the input magnetic field may be obtained:

$$\frac{{V}_{out}}{B} = \frac{- j ω {μ}_{app} {N}_{p} SG}{1 + j ω ( {CR}_{sc} + \frac{MG}{( {R}_{fb} + j ω {L}_{s} )} ) + {( j ω )}^{2} {L}_{pc}} ; \qquad ( 6 )$$

For example, the sensitivity of the induction coil (represented by Vᵢ, dashed line) and the sensitivity of the magnetic field sensor (represented by Vₒᵤₜ, solid line) are shown in FIG. 2.

The magnetic flux negative feedback may effectively flatten the sensitivity of the magnetic field sensor near a single resonance frequency.

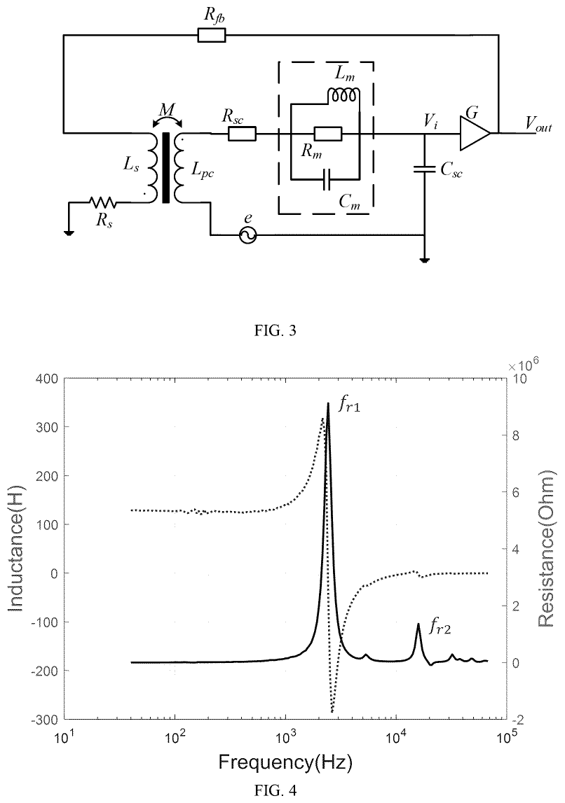

However, the coil of a magnetic field sensor usually has a plurality of resonance points (or resonance peaks) within its operating bandwidth. To address this complexity, the conventional series resonant model is extended by providing at least one parallel resonance equivalent circuit (also referred to as parallel resonance equivalent model), as shown in the rectangular dashed box in FIG. 3. This parallel resonance equivalent circuit introduces additional resistor Rₘ, capacitor Cₘ, and inductor Lₘ. The introduction of the parallel resonance equivalent circuit may describe or simulate the magnetic field sensor more comprehensively.

In the parallel resonance equivalent circuit, a small inductance is extracted from the total inductance of the induction coil as the equivalent resonant inductance Lₘ. The equivalent resonant capacitance Cₘ is jointly determined by the second resonance frequency point fₘ and the value of the equivalent resonant inductance. The equivalent resonant resistance Rₘ is determined by the Q factor measured at the second resonance point and is usually a relatively large resistance value.

$${C}_{m} = \frac{1}{{L}_{m} \times \sqrt{{( 2 π {f}_{m} )}^{2}}} ; \qquad ( 7 )$$

$${R}_{m} = \frac{Q}{2 π {f}_{m} {C}_{m}} ; \qquad ( 8 )$$

To estimate the values of the equivalent components in the equivalent circuit model shown in FIG. 3, two steps are required: impedance test and coil induced voltage test to estimate all parameters.

### 1. Regarding the Impedance Test:

Taking a dual-resonance coil as an example, the AC impedance test results of the coil obtained using an impedance analyzer (model 4294A) are shown in FIG. 4. The inductance value measured at 40 Hz is denoted as Lₜₑₛₜ. The dashed line represents inductance, and the solid line represents resistance. The first resonance frequency corresponding to the first resonance peak is fᵣ₁, and the second resonance frequency corresponding to the second resonance peak is fᵣ₂. Then:

$${L}_{test} = {L}_{m} + {L}_{pc} ; \qquad ( 9 )$$

$${C}_{sc} = \frac{1}{{L}_{test} \times \sqrt{{( 2 π {f}_{r 1} )}^{2}}} ; \qquad ( 10 )$$

$${C}_{m} = \frac{1}{{L}_{m} \times \sqrt{{( 2 π {f}_{r 2} )}^{2}}} ; \qquad ( 11 )$$

If Lₘ is 10 H, the value of the equivalent inductance L_{pc} may be calculated. In addition, the resistance measured by the impedance analyzer includes the loss of the magnetic core. Therefore, the coil resistance R_{sc} in the model may be determined from the measured DC resistance of the coil. At this point, the parameter values in the dual-resonance point model of the magnetic field sensor may be derived from the impedance test results, as detailed in Table 1 below.

TABLE 1
Magnetic Field Sensor Parameters

| Component | Parameter | Value | |
|---|---|---|---|
| Induction coil (magnetic | e | 25e−3 | mV/nT |
| core) related parameters | L_{pc} | 127.3 | H |
| | R_{sc} | 261.7 | Ohm |
| | fᵣ₁(first resonance | 2432 | Hz |
| | frequency) | | |
| | C_{sc} | 31 | pF |
| | Lₘ | 10 | H |
| | Rₘ | 10⁷ | Ohm |
| | fᵣ₂(second resonance | 15903 | Hz |
| | frequency) | | |
| | Cₘ | 10 | pF |
| Test equipment related | Cₛₐ | 500 | pF |
| parameters | Cₛₘ | 8 | pF |
| | Rₜ | 10⁶ | Ohm |
| Circuit part related | C_{ca} | 200 | pF |
| parameters | C_{cm} | 20 | pF |
| | R_{c} | 8 × 10⁶ | Ohm |
| | Gain | 8000 | |
| | R_{fb} | 58 | kΩ |
| Feedback coil related | Lₛ | 596 | uH |

| | | |
|---|---|---|
| parameters | M | 0.2862 |

Based on circuit theory and the dual-resonance point model, the analytical expression for the induced voltage Vᵢ is converted from formula (2) to formula (12), as shown below:

$${V}_{i} ( f ) = \frac{\frac{1}{j ω ( {C}_{sc} + {C}_{sa} ) + \frac{1}{{R}_{t}}}}{\begin{matrix}{R}_{sc} + j ω {L}_{pc} + \frac{1}{\frac{1}{j ω {L}_{m}} + j ω ( {C}_{m} + {C}_{sm} ) + \frac{1}{{R}_{m}}} + \\ \frac{1}{j ω ( {C}_{sc} + {C}_{sa} ) + \frac{1}{{R}_{t}}}\end{matrix}} e ( f ) ; \qquad ( 12 )$$

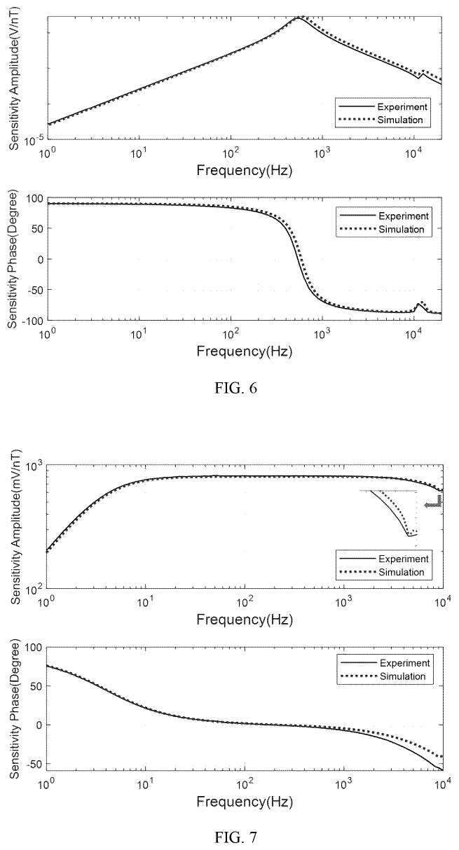

By substituting the values in Table 1, the sensitivity of the induced voltage may be simulated and calculated. A comparison of the simulation results with the actual results is shown in FIG. 6. The upper part of FIG. 6 reflects the sensitivity (amplitude) results, and the lower part reflects the sensitivity (phase) results. Meanwhile, the sensitivity was measured using a solenoid calibration system. The scale factor of the solenoid is 16.934 nT/mA. The frequency scanner in the system is a dynamic signal analyzer (model 35670A).

It may be observed that the actual measurement results of the magnetic field sensor are basically consistent with the simulation results, indicating that the dual-resonance point model is valid.

### 2. Regarding the Magnetic Field Sensor Sensitivity Test:

By deriving the transfer function of the magnetic flux negative feedback magnetic field sensor, it may be observed that formula (5) remains unchanged, while formula (4) is revised to formula (13), as shown below:

$$A = \frac{{V}_{i}}{e} = \frac{\frac{1}{j ω ( {C}_{sc} + {C}_{ca} ) + \frac{1}{{R}_{c}}}}{\begin{matrix}{R}_{sc} + j ω {L}_{pc} + \frac{1}{\frac{1}{j {ω}_{{L}_{m}}} + j ω ( {C}_{m} + {C}_{cm} ) + \frac{1}{{R}_{m}}} + \\ \frac{1}{j ω ( {C}_{sc} + {C}_{ca} ) + \frac{1}{{R}_{c}}}\end{matrix}} ; \qquad ( 13 )$$

The expression in formula (13) may be simplified as:

$$A = \frac{{N}_{A}}{{D}_{A}} ; \qquad ( 14 )$$

where the numerator NA:

$${N}_{A} = \frac{1}{j ω ( {C}_{sc} + {C}_{ca} ) + \frac{1}{{R}_{c}}} ; \qquad ( 15 )$$

Denominator DA:

$${D}_{A} = {R}_{sc} + j ω {L}_{pc} + \frac{j ω {L}_{m} {R}_{m}}{{R}_{m} + j ω {L}_{m} - {ω}^{2} {L}_{m} {R}_{m} ( {C}_{m} + {C}_{cm} )} + \frac{{R}_{c}}{1 + j ω {R}_{c} ( {C}_{sc} + {C}_{ca} )} ; \qquad ( 16 )$$

By substituting formulas (13) and (5) into formula (3), and simplifying the numerator and denominator, the sensitivity of the sensor may be obtained:

$$\frac{{V}_{out}}{B} = \frac{- j ω {μ}_{app} {N}_{p} S * {N}_{A} * G}{{D}_{A} + {N}_{A} * G * \frac{j ω M}{{R}_{fb} + j ω {L}_{s}}} ; \qquad ( 17 )$$

Different from calculating the induced voltage considering the input impedance of the equipment, here the coil is connected to the amplifying circuit, so the input impedance of the circuit needs to be considered. The input resistance R_{c} of the amplifying circuit is 4 GOhm, and the input capacitance C_{ca} is 200 pF. Due to the isolation effect of the circuit, the input parameters of the test equipment no longer need to be considered in this scenario.

Furthermore, because the overall sensor introduces a negative feedback coil, a shielding layer, and a calibration coil, the inter-turn capacitance Cₘ existing between these coils will increase to 20 pF. The specific parameter is listed in Table 1. Similarly, a comparison of the simulation results and the actual test results of the magnetic field sensor is shown in FIG. 7. The upper part of FIG. 7 reflects the sensitivity (amplitude) results, and the lower part reflects the sensitivity (phase) results.

Considering the differences between the design and actual implementation of the sensor filter, the test results show consistency between the experiment and the simulation results. It is noteworthy that by introducing the parallel resonance equivalent circuit model corresponding to the second resonance point, the fluctuation of the measured sensitivity of the sensor at 9 kHz is effectively explained.

The dual-resonance model of the magnetic field sensor is as described above, and its coil parameters may be obtained through impedance analysis tests. By incorporating the parameters of the test equipment and directly connecting the coil output to the equipment to measure the sensitivity of the induced voltage, the results are consistent with the simulation. Furthermore, by integrating the circuit parameters and connecting the coil to the circuit to test the sensitivity of the sensor, the results are also consistent with the simulation results. Therefore, the proposed dual-resonance model of the sensor has been verified as correct and effective.

Currently, the inductive magnetic field sensor uses a single resonance point model, which does not comprehensively describe the sensor. The multi-resonance point equivalent circuit model for the inductive magnetic field sensor and establishing method thereof proposed in the present disclosure introduces a parallel resonance equivalent circuit for the second resonance point of the coil, which is a component of the magnetic field sensor, thereby explaining the change in sensor sensitivity and effectively expanding the sensor theory.

So far, the embodiments of the present disclosure have been described in detail with reference to the accompanying drawings. It should be noted that implementations not shown or described in the drawings or the specification are in forms known to those of ordinary skill in the art and are not described in detail. Furthermore, the above definitions of various elements and methods are not limited to the specific structures, shapes, or manners mentioned in the embodiments, and those of ordinary skill in the art may simply change or replace them.

In addition, in the present disclosure, unless specifically indicated, ordinal numbers such as “first” and “second” are only used to distinguish multiple elements having the same name and do not imply any hierarchy, order of execution, or manufacturing sequence between them. A “first” element and a “second” element may appear together in the same component or appear separately in different components. The existence of an element with a larger ordinal number does not necessarily imply the existence of another element with a smaller ordinal number.

In the present disclosure, unless specifically indicated, so-called feature A “or” or “and/or” feature B means A exists alone, B exists alone, or A and B exist simultaneously; so-called feature A “and” feature B means A and B exist simultaneously; so-called “include”, “comprise”, “have”, “contain” means including but not limited to.

Furthermore, unless specifically described or steps must occur in sequence, the order of the above steps is not limited to those listed and may be changed or rearranged according to desired design. Moreover, the above embodiments may be mixed and used with each other or with other embodiments based on design and reliability considerations, i.e., technical features in different embodiments may be freely combined to form more embodiments.

The above specific embodiments further describe the purpose, technical solutions, and beneficial effects of the present disclosure in detail. It should be understood that the above are only specific embodiments of the present disclosure and are not intended to limit the present disclosure. Any modifications, equivalent substitutions, improvements, etc. made within the spirit and principle of the present disclosure shall be included in the protection scope of the present disclosure.

What is claimed is:

1. A multi-resonance point equivalent circuit model for an inductive magnetic field sensor, wherein the inductive magnetic field sensor comprises an electromagnetic induction assembly, a feedback coil, and an amplifying circuit, and the multi-resonance point equivalent circuit model comprises:
an output terminal;
an RLC equivalent circuit of the electromagnetic induction assembly, comprising an equivalent model of a magnetic core and an RLC equivalent circuit coupled and connected to the magnetic core;
an equivalent circuit of the amplifying circuit, wherein one terminal of the equivalent circuit of the amplifying circuit is connected to the RLC equivalent circuit, and the other terminal of the equivalent circuit of the amplifying circuit is connected to the output terminal;
an equivalent circuit of a negative feedback coil, wherein one terminal of the equivalent circuit of the negative feedback coil is connected to the output terminal, and the other terminal of the equivalent circuit of the negative feedback coil is coupled and connected to the RLC equivalent circuit of the electromagnetic induction assembly; and
at least one parallel resonance equivalent circuit, connected between the RLC equivalent circuit of the electromagnetic induction assembly and the equivalent circuit of the amplifying circuit, and configured to suppress a resonance peak corresponding to a resonance point within an operating frequency band of the inductive magnetic field sensor.

2. The multi-resonance point equivalent circuit model according to claim 1, wherein the electromagnetic induction assembly comprises the magnetic core and an induction coil wound on the magnetic core, and the RLC equivalent circuit of the electromagnetic induction assembly comprises an equivalent inductance L_{pc} and an equivalent resistance R_{sc} connected in series and an equivalent capacitance C_{sc}, wherein the equivalent inductance L_{pc} and the equivalent resistance R_{sc} connected in series are connected in parallel across two terminals of the equivalent capacitance C_{sc}.

3. The multi-resonance point equivalent circuit model according to claim 2, wherein the at least one parallel resonance equivalent circuit is provided based on resonance point information within the operating frequency band of the inductive magnetic field sensor, and the resonance point information comprises a number of resonance peaks and a frequency of the resonance point corresponding to each resonance peak.

4. The multi-resonance point equivalent circuit model according to claim 3, wherein the at least one parallel resonance equivalent circuit is selectively provided according to the number of resonance peaks.

5. The multi-resonance point equivalent circuit model according to claim 3, wherein a number of parallel resonance equivalent circuits provided is determined based on the number of resonance peaks.

6. The multi-resonance point equivalent circuit model according to claim 2, wherein the parallel resonance equivalent circuit comprises an equivalent resonant inductance Lₘ, an equivalent resonant resistance Rₘ, an equivalent resonant capacitance Cₘ, and an equivalent inter-turn capacitance Cₛₘ connected in parallel, wherein the equivalent resonant resistance Rₘ is connected in series with the equivalent resistance R_{sc}, and the equivalent resonant inductance Lₘ is derived from a part of the equivalent inductance L_{pc}.

7. The multi-resonance point equivalent circuit model according to claim 3, wherein the parallel resonance equivalent circuit comprises an equivalent resonant inductance Lₘ, an equivalent resonant resistance Rₘ, an equivalent resonant capacitance Cₘ, and an equivalent inter-turn capacitance Cₛₘ connected in parallel, wherein the equivalent resonant resistance Rₘ is connected in series with the equivalent resistance R_{sc}, and the equivalent resonant inductance Lₘ is derived from a part of the equivalent inductance L_{pc}.

8. The multi-resonance point equivalent circuit model according to claim 4, wherein the parallel resonance equivalent circuit comprises an equivalent resonant inductance Lₘ, an equivalent resonant resistance Rₘ, an equivalent resonant capacitance Cₘ, and an equivalent inter-turn capacitance Cₛₘ connected in parallel, wherein the equivalent resonant resistance Rₘ is connected in series with the equivalent resistance R_{sc}, and the equivalent resonant inductance Lₘ is derived from a part of the equivalent inductance L_{pc}.

9. The multi-resonance point equivalent circuit model according to claim 5, wherein the parallel resonance equivalent circuit comprises an equivalent resonant inductance Lₘ, an equivalent resonant resistance Rₘ, an equivalent resonant capacitance Cₘ, and an equivalent inter-turn capacitance Cₛₘ connected in parallel, wherein the equivalent resonant resistance Rₘ is connected in series with the equivalent resistance R_{sc}, and the equivalent resonant inductance Lₘ is derived from a part of the equivalent inductance L_{pc}.

10. The multi-resonance point equivalent circuit model according to claim 6, wherein a solution formula for the equivalent resonant capacitance Cₘ is:
$${C}_{m} = \frac{1}{{L}_{m} \times \sqrt{{( 2 π {f}_{m} )}^{2}}} ;$$
a solution formula for the equivalent resonant resistance Rₘ is:
$${R}_{m} = \frac{Q}{2 π {f}_{m} {C}_{m}} ;$$
wherein Lₘ is a value of the equivalent resonant inductance, fₘ is a frequency of the resonance point corresponding to the parallel resonance equivalent circuit, and Q represents a quality factor of the parallel resonance equivalent circuit.

11. The multi-resonance point equivalent circuit model according to claim 2, wherein one terminal of the equivalent capacitance C_{sc} is grounded, and the other terminal of the equivalent capacitance C_{sc} is connected to the equivalent circuit of the amplifying circuit.

12. The multi-resonance point equivalent circuit model according to claim 3, wherein one terminal of the equivalent capacitance C_{sc} is grounded, and the other terminal of the equivalent capacitance C_{sc} is connected to the equivalent circuit of the amplifying circuit.

13. The multi-resonance point equivalent circuit model according to claim 4, wherein one terminal of the equivalent capacitance C_{sc} is grounded, and the other terminal of the equivalent capacitance C_{sc} is connected to the equivalent circuit of the amplifying circuit.

14. The multi-resonance point equivalent circuit model according to claim 5, wherein one terminal of the equivalent capacitance C_{sc} is grounded, and the other terminal of the equivalent capacitance C_{sc} is connected to the equivalent circuit of the amplifying circuit.

15. The multi-resonance point equivalent circuit model according to claim 2, wherein the equivalent circuit of the negative feedback coil comprises a feedback resistor R_{fb}, an equivalent inductance Lₛ of the negative feedback coil, and an equivalent resistance Rₛ of the negative feedback coil connected in series in sequence, wherein one terminal of the equivalent circuit of the negative feedback coil is connected to an output terminal of the equivalent circuit of the amplifying circuit, and the other terminal of the equivalent circuit of the negative feedback coil is grounded.

16. The multi-resonance point equivalent circuit model according to claim 3, wherein the equivalent circuit of the negative feedback coil comprises a feedback resistor R_{fb}, an equivalent inductance Lₛ of the negative feedback coil, and an equivalent resistance Rₛ of the negative feedback coil connected in series in sequence, wherein one terminal of the equivalent circuit of the negative feedback coil is connected to an output terminal of the equivalent circuit of the amplifying circuit, and the other terminal of the equivalent circuit of the negative feedback coil is grounded.

17. The multi-resonance point equivalent circuit model according to claim 4, wherein the equivalent circuit of the negative feedback coil comprises a feedback resistor R_{fb}, an equivalent inductance Lₛ of the negative feedback coil, and an equivalent resistance Rₛ of the negative feedback coil connected in series in sequence, wherein one terminal of the equivalent circuit of the negative feedback coil is connected to an output terminal of the equivalent circuit of the amplifying circuit, and the other terminal of the equivalent circuit of the negative feedback coil is grounded.

18. The multi-resonance point equivalent circuit model according to claim 5, wherein the equivalent circuit of the negative feedback coil comprises a feedback resistor R_{fb}, an equivalent inductance Lₛ of the negative feedback coil, and an equivalent resistance Rₛ of the negative feedback coil connected in series in sequence, wherein one terminal of the equivalent circuit of the negative feedback coil is connected to an output terminal of the equivalent circuit of the amplifying circuit, and the other terminal of the equivalent circuit of the negative feedback coil is grounded.

19. A method for establishing the multi-resonance point equivalent circuit model according to claim 1, wherein the inductive magnetic field sensor comprises the electromagnetic induction assembly, the feedback coil, and the amplifying circuit, and the method comprises:
establishing the RLC equivalent circuit of the electromagnetic induction assembly;
establishing the equivalent circuit of the amplifying circuit connected to the RLC equivalent circuit;
establishing the equivalent circuit of the negative feedback coil, so as to establish an initial equivalent circuit model for the inductive magnetic field sensor;
determining resonance point information within the operating frequency band of the inductive magnetic field sensor based on the initial equivalent circuit model for the magnetic field sensor; and
providing at least one parallel resonance equivalent circuit according to the resonance point information to suppress a resonance peak corresponding to a resonance point within the operating frequency band of the inductive magnetic field sensor, so as to establish the multi-resonance point equivalent circuit model for the inductive magnetic field sensor.
